(19) United States
(12) Patent Application Publication
(10) Pub. No.: US 2015/0349230 A1
(43) Pub. Date: Dec. 3, 2015

(54) HEAT RADIATION SHEET FOR BOARD, MANUFACTURING METHOD THEREOF, AND HEAT RADIATION BOARD

(71) Applicant: Samsung Electro-Mechanics Co., Ltd., Suwon-si (KR)

(72) Inventors: Kwang Soo KIM, Suwon-Si (KR); Young Hoon KWAK, Suwon-Si (KR); Joon Seok CHAE, Suwon-Si (KR)

(73) Assignee: SAMSUNG ELECTRO-MECHANICS CO., LTD., Suwon-si (KR)

(21) Appl. No.: 14/602,725

(22) Filed: Jan. 22, 2015

(30) Foreign Application Priority Data
May 27, 2014 (KR) 10-2014-0063710

(51) Int. Cl. H01L 33/64; B32B 15/08

(52) U.S. Cl. CPC H01L 33/641; B32B 15/08; B32B 2307/30; B32B 2264/107; B32B 2264/105; B32B 2264/102; B32B 2457/14

(57) ABSTRACT

A heat radiation sheet for a board including: composite fillers including metal particles and ceramic particles disposed on surfaces of the metal particles; and a base resin, and a manufacturing method of a heat radiation sheet for a board may include: preparing metal particles and ceramic particles; disposing the ceramic particles on surfaces of the metal particles by mixing the metal particles and the ceramic particles with each other; forming oxidized layers on exposed surfaces of the metal particles; and forming a prepreg by mixing composite fillers including the metal particles and the ceramic particles and a base resin with each other.

### CROSS-REFERENCE TO RELATED APPLICATION

This application claims the priority and benefit of Korean Patent Application No. 10-2014-0063710 filed on May 27, 2014, with the Korean Intellectual Property Office, the disclosure of which is incorporated herein by reference.

### BACKGROUND

The present disclosure relates to a heat radiation sheet for a board, a manufacturing method thereof, and a heat radiation board.

A circuit board, including circuit patterns formed on an electrical insulating substrate, has an electronic component, and the like, mounted thereon. The electronic component may be a heat generating device emitting a large amount of heat, for example, a light emitting diode (LED), or the like. Heat emitted from the heat generating device may raise a temperature of the circuit board to cause a malfunction of the heat generating device or a problem in reliability of the heat generating device.

The circuit board including the heat generating device uses a metal plate as a base in order to radiate the heat generated from the heat generating device. Particularly, in order to improve heat radiation properties of the metal plate to stabilize an operation of the heat generating device, thermal conduction properties of an insulating film interposed between the metal plate and a metal layer should be improved.

In order to improve the thermal conduction properties of the insulating film, a technology of allowing a thermal conductive filling material to be contained in the insulating film has been reported, and the insulating film may contain a resin compound such as an epoxy resin, or the like, and contain alumina, aluminum nitride, boron nitride, or the like, as the thermal conductive filling material.

### RELATED ART DOCUMENT

(Patent Document 1) U.S. Pat. No. 7,602,051

### SUMMARY

An aspect of the present disclosure may provide a heat radiation sheet for a board, a manufacturing method thereof, and a heat radiation board.

According to an aspect of the present disclosure, a heat radiation sheet for a board may include: composite fillers including metal particles and ceramic particles; and a base resin.

The ceramic particles may be disposed on surfaces of the metal particles.

The metal particles may include oxidized layers formed on surfaces that do not have the ceramic particles disposed thereon to thereby be exposed.

According to another aspect of the present disclosure, a manufacturing method of a heat radiation sheet for a board may include: preparing metal particles and ceramic particles;

disposing the ceramic particles on surfaces of the metal particles by mixing the metal particles and the ceramic particles with each other; forming oxidized layers on exposed surfaces of the metal particles; and forming a prepreg by mixing composite fillers including the metal particles and the ceramic particles and a base resin with each other.

According to another aspect of the present disclosure, a heat radiation board may include the heat radiation sheet as described above.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically showing a heat radiation sheet for a board according to an exemplary embodiment in the present disclosure;

FIG. 2 is a flow chart showing a manufacturing method of a heat radiation sheet for a board according to another exemplary embodiment in the present disclosure;

FIGS. 3A through 3D are cross-sectional views schematically showing operations of a manufacturing method of a heat radiation sheet for a board according to an exemplary embodiment in the present disclosure; and

FIG. 4 is a cross-sectional view schematically showing a heat radiation board according to another exemplary embodiment in the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Heat Radiation Sheet

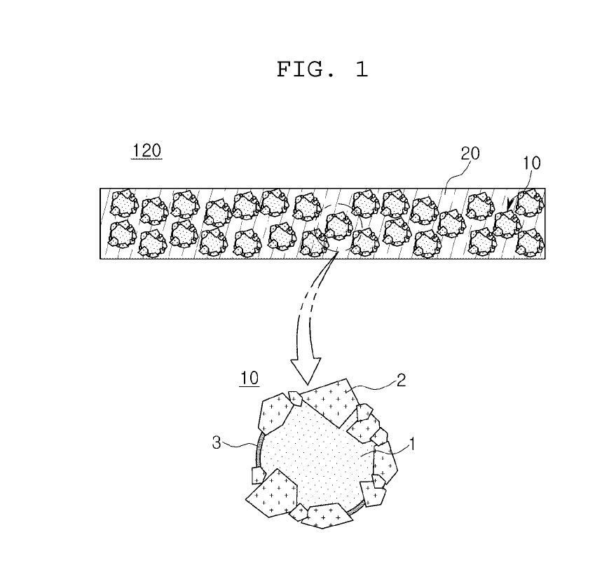

FIG. 1 is a cross-sectional view schematically showing a heat radiation sheet according to an exemplary embodiment in the present disclosure.

Referring to FIG. 1, a heat radiation sheet 120 according to an exemplary embodiment in the present disclosure may include composite fillers 10 and a base resin 20, and may be a heat radiation sheet for a board applied to a board.

The composite filler 10 may include metal particles 1 and ceramic particles 2 disposed on surfaces of the metal particles. The ceramic particles 2 may be integrated with the metal particles 1.

The composite filler 10 may include the metal particles having high thermal conductivity to improve thermal conduction efficiency of the heat radiation sheet.

Unlike an exemplary embodiment in the present disclosure, in the case in which the heat radiation sheet is formed of only ceramic fillers, there may be a restriction in applying the heat radiation sheet to a high heat radiation product group. Generally, there may be a limitation in a content of fillers included in the heat radiation sheet since a problem may occur in withstand voltage and thermal property controls due to dispersion of the fillers. In this case, when the fillers are the ceramic fillers, efficiency of the heat radiation sheet may be low due to a limitation of thermal conductivity of ceramic.

However, according to an exemplary embodiment in the present disclosure, the composite fillers 10 included in the heat radiation sheet 120 may include the metal particles 1 to improve thermal conductivity as compared with the case in which the heat radiation sheet includes only the ceramic fillers.

Since the heat radiation sheet 120 according to an exemplary embodiment in the present disclosure serves as an insulating layer at the time of being applied to a board, even though the composite fillers included in the heat radiation sheet include the metal, an insulation property of the heat radiation sheet needs to be secured.

Unlike an exemplary embodiment in the present disclosure, in the case in which the fillers included in the heat radiation sheet are formed of only metal particles, even though most of the metal particles are buried in a base resin, it may be difficult to secure an electrical insulation property of the heat radiation sheet due to exposure of some of the metal particles to a surface of the heat radiation sheet or a contact or a tunneling effect between the metal particles.

In addition, unlike an exemplary embodiment in the present disclosure, in the case in which the ceramic particles are not disposed on the surfaces of the metal particles, but are dispersed separately from the metal particles and are included in the heat radiation sheet, a leakage current may be generated at the time of applying a high voltage to the heat radiation sheet, and it may be difficult to secure a withstand voltage.

However, according to an exemplary embodiment in the present disclosure, the ceramic particles 2 may be disposed on the surfaces of the metal particles 1 to suppress the contact and the tunneling effect between the metal particles, thereby securing an insulation property.

According to an exemplary embodiment in the present disclosure, a particle size of the ceramic particle 2 included in the composite filler 10 may be 0.3 to 1.4 times the particle size of the metal particle 1 included in the composite filler in order to efficiently dispose the ceramic particles on the surfaces of the metal particles.

In the case in which the particle size of the ceramic particle is smaller than 0.3 times the particle size of the metal particle, an insulation property improving effect may hardly appear, and in the case in which the particle size of the ceramic particle is larger than 1.4 times the particle size of the metal particle, a large heat radiation property improving effect may not appear and adhesion of the ceramic particles adhered to the metal particles may be lower than adhesion required at the time of manufacturing the board, such that it may be difficult to use the heat radiation sheet.

According to an exemplary embodiment in the present disclosure, a volume ratio (volume of metal particles:volume of ceramic particles) between the metal particles 1 and the ceramic particles 2 included in the composite filler 10 may be 10:8 to 10:28. In the case in which a volume ratio of the ceramic particles 2 to the metal particles 1 exceeds 10:28, adhesion between the metal particles and the ceramic particles may be decreased to 1.2 Kgf or less, which is minimal adhesion required between the heat radiation sheet and a metal layer disposed on the heat radiation sheet.

Adhesion between the composite filler 10 and the base resin 20 enclosing the composite filler needs to be at least equal to or larger than adhesion between the heat radiation sheet and the metal layer disposed on the heat radiation sheet, and the adhesion between the ceramic particles and the metal particles may be equal to or larger than adhesion between the composite filler 10 and the base resin 20 in order to adhere the ceramic particles 2 and the metal particles 1 to each other.

According to an exemplary embodiment in the present disclosure, a volume ratio of the ceramic particles 2 to the metal particles 1 may be less than 10:28, such that adhesion between the ceramic particles 2 and the metal particles 1 included in the composite filler 10 may be equal to or larger than adhesion between the composite filler 10 and the base resin 20.

In the case in which the volume ratio of the ceramic particles 2 to the metal particles 1 is less than 10:8, an insulation property of the heat radiation sheet 120 may not be secured and an insulation withstand voltage of the heat radiation sheet may become 4 kV or less, which is an insulation withstand voltage required for the heat radiation sheet to be used for a power semiconductor module, such that it may be difficult to apply the heat radiation sheet to a heat radiation board.

According to an exemplary embodiment in the present disclosure, the metal particle 1 may be a non-magnetic metal, and may include for example, one or more of copper (Cu), aluminum (Al), tin (Sn), and titanium (Ti).

In the present specification, the non-magnetic metal, a metal that is not affected by a magnetic field, may include a paramagnetic metal and a diamagnetic metal.

A magnetic metal may have a metal structure formed of grains having a size smaller than that of the non-magnetic material in order to increase magnetism (magnetic permeability), and may have a low heat conduction effect since the number of grain boundaries is many. However, the non-magnetic metal may have a metal structure formed of grains having a size larger than that of the magnetic metal, thereby decreasing heat conduction deterioration due to grain boundaries.

According to an exemplary embodiment in the present disclosure, the ceramic particles 2 may be attached to the surfaces of the metal particles 1 by physical coupling force, such that the metal particles 1 and the ceramic particles 2 may be integrated with each other. For example, the ceramic particles 2 may be disposed on the surfaces of the metal particles 1 without a separate adhesive, and be disposed in a form in which partial regions thereof are stuck into the surfaces of the metal particles 1. According to an exemplary embodiment in the present disclosure, hardness of the ceramic particles 2 may be larger than that of the metal particles 1 in order to physically couple the ceramic particles 2 and the metal particles 1 to each other.

In addition, the ceramic particles 2 may have a prismatic shape rather than a spherical shape in order to facilitate coupling between the metal particles 1 and the ceramic particles 2.

The ceramic particles 2 may include one or more of alumina (Al₂O₃), aluminum nitride (AlN), boron nitride (BN), silicon dioxide (SiO₂), and silicon carbide (SiC) having relatively high thermal conductivity among ceramic materials, but are not limited thereto.

The metal particle 1 may have approximately a spherical shape. The metal particle may have a substantially spherical shape rather than a complete spherical shape.

According to an exemplary embodiment in the present disclosure, the metal particles 1 may include oxidized layers 3 formed by oxidizing surfaces of regions in which the ceramic particles are not disposed on the surfaces of the metal particles 1.

The oxidized layer 3 may provide an insulation property to the surface of the metal particle on which the ceramic particle is not disposed in the composite filler.

Unlike an exemplary embodiment in the present disclosure, in the case in which the filler does not include the ceramic particles, but is formed of the metal particles having the oxidized layers formed on the surfaces thereof, an insulation property and a withstand voltage property of the heat radiation board may not be sufficiently secured. In addition, in the case in which the insulation property is to be implemented by only the oxidized layer formed on the surface of the metal particle, the surface of the metal particle may not be uniformly oxidized, and thermal conductivity of an oxidized layer region of the metal particle may be lower than that of the ceramic particle, such that a heat radiation property may be deteriorated.

Therefore, according to an exemplary embodiment in the present disclosure, an insulation property and a withstand voltage property of the composite filler 10 may be mainly secured by the ceramic particles 2 disposed on the surfaces of the metal particles 1, and the oxidized layers 3 may be formed in regions in which the ceramic particles are not disposed to reinforce an insulation property, whereby the composite filler 10 having high thermal conduction efficiency and an improved insulating property and withstand voltage property and a heat radiation sheet including the same may be provided.

A thickness of the oxidized layer 3 may be equal to or lager than a value obtained by multiplying a cubic root of the volume ratio (volume of ceramic particles/volume of metal particles) of the ceramic particles to the metal particles by 1.5 μm. When it is assumed that the thickness of the oxidized layer 3 formed on the surface of the metal particle is A μm, a preferable lower limit range of A may be represented by Mathematical Expression 1.

### Mathematical Expression 1

A≧(Volume of Ceramic Particles/Volume of Metal Particles)^{1/3}×1.5 μm

In the case in which the thickness A of the oxidized layer is less than (Volume of Ceramic Particles/Volume of Metal Particles)^{1/3}×1.5 μm, it may be difficult to secure a withstand voltage property for allowing the heat radiation sheet to serve as an insulating layer and serve to prevent a short-circuit due to a leakage current at the time of applying a high voltage.

According to an exemplary embodiment in the present disclosure, a thickness of the oxidized layer may be 1.4 μm to 2.2 μm. In the case in which the thickness of the oxidized layer is less than 1.4 μm, it may be difficult to secure the withstand voltage property, and in the case in which the thickness of the oxidized layer exceeds 2.2 μm, thermal conduction efficiency may be deteriorated.

The base resin 20 is not particularly limited as long as it may be used for an insulating layer of a general board. The base resin 20 may include one or more of an epoxy based resin, a polyimide based resin, a polyether based resin, a polysulfone based resin, a polycarbonate based resin, and a polyester based resin, but is not limited thereto.

The epoxy resin is not particularly limited, but may be, for example, a phenolic glycidyl ether type epoxy resin such as a phenol novolac type epoxy resin, a cresol novolac type epoxy resin, a naphthol-modified novolac type epoxy resin, a bisphenol A type epoxy resin, a bisphenol F type epoxy resin, a biphenyl type epoxy resin, a tripheny type epoxy resin, or the like, a dicyclopentadiene type epoxy resin having a dicyclopentadiene skeleton, a naphthalene type epoxy resin having a naphthalene skeleton, a dihydroxybenzopyran type epoxy resin, a glycidylamine type epoxy resin using polyamine as a raw material, such as diaminophenylmethane, or the like, a triphenol methane type epoxy resin, a tetraphenyl ethane type epoxy resin, or a mixture thereof, or the like.

A more specific example of the epoxy resin may be N,N, N′,N′-tetraglycidyl-4,4′-methylenebisbenzenamine, polyglycidyl ether of o-cresol-formaldehyde novolac, or a mixture thereof. However, the present disclosure is not limited thereto.

The heat radiation sheet 120 according to an exemplary embodiment in the present disclosure may further include a hardening accelerator for hardening the base resin. Here, the hardening accelerator may include one or more of a metal based hardening accelerator, an imidazole based hardening accelerator, and an amine based hardening accelerator, but is not limited thereto.

The heat radiation sheet 120 according to an exemplary embodiment in the present disclosure may further include another reinforcing material. Another reinforcing material is not particularly limited, but may include a reinforcing material selected from a group consisting of, for example, glass fiber, thermoplastic liquid crystal polymer fiber such as aramid fiber, or the like, quartz fiber, and the like.

The composite filler 10 may have a particle size corresponding to 0.1 to 0.15 times the thickness of the heat radiation sheet 120, but is not limited thereto. In the case in which a particle size of the composite filler is less than 0.1 times the thickness of the heat radiation sheet, a heat radiation property may be deteriorated, and in the case in which a particle size of the composite filler exceeds 0.15 times the thickness of the heat radiation sheet, an insulation property may be deteriorated.

In a description of an exemplary embodiment in the present disclosure, particle sizes of the composite filler 10, the metal particle 1, and the ceramic particle 2 may be defined as a length of the longest straight line among straight lines connecting two points on surfaces thereof to each other.

The composite fillers 10 may be dispersed and disposed in the base resin 20.

### Manufacturing Method of Heat Radiation Sheet for Board

Since a description for the base resin and the composite filler in a description for a manufacturing method of a heat radiation sheet for a board according to the present exemplary embodiment is overlapped with a description for the heat radiation sheet for a board described above, it will be omitted, and a difference between a manufacturing method of a heat radiation sheet for a board and the heat radiation sheet for a board will be mainly described.

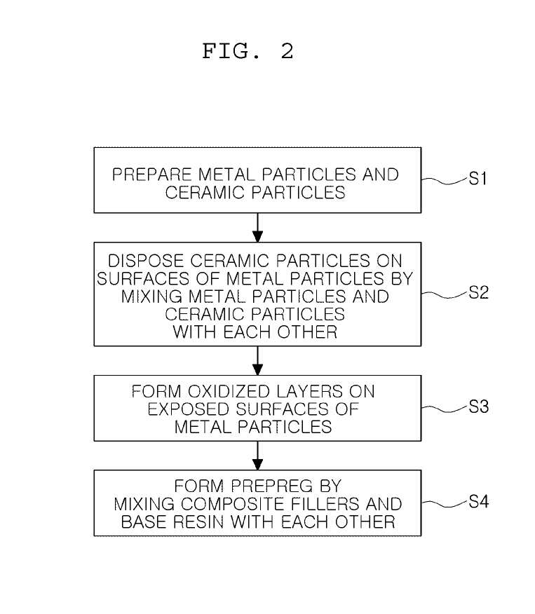

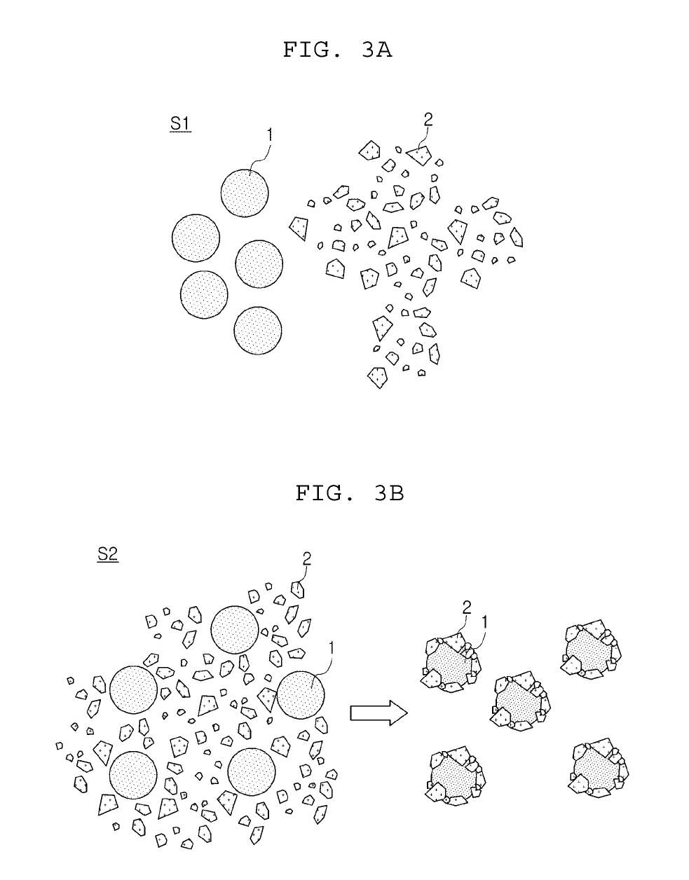

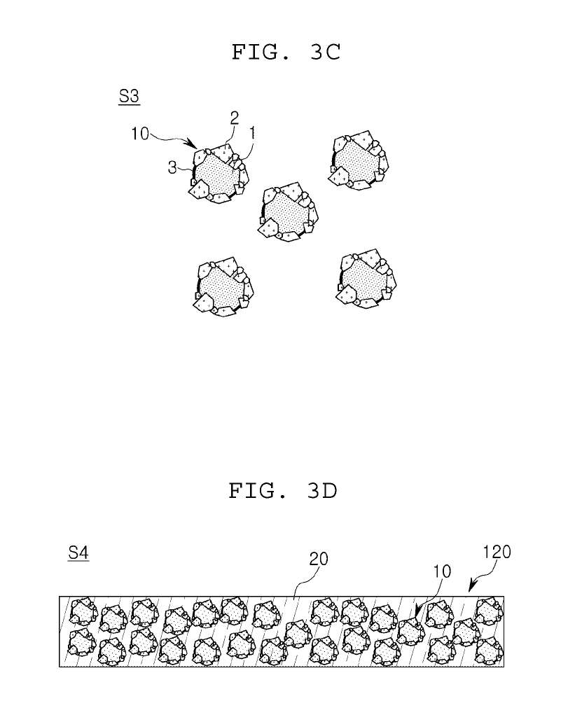

FIG. 2 is a flow chart showing a manufacturing method of a heat radiation sheet for a board according to another exemplary embodiment in the present disclosure; and FIGS. 3A through 3D are cross-sectional views schematically showing operations of a manufacturing method of a heat radiation sheet for a board according to an exemplary embodiment in the present disclosure.

Referring to FIG. 2, a manufacturing method of a heat radiation sheet for a board according to the present exemplary embodiment may include preparing the metal particles and the ceramic particles (S1), disposing the ceramic particles on the surfaces of the metal particles by mixing the metal particles and the ceramic particles with each other (S2), forming the oxidized layers on the exposed surfaces of the metal particles (S3), and forming a prepreg by mixing the composite fillers and the base resin with each other.

In the preparing (S1) of the metal particles and the ceramic particles, as shown in FIG. 3A, the metal particles 1 and the ceramic particles 2 may be prepared, respectively. The metal particle and the ceramic particle may have a substantially spherical shape and a prismatic shape, respectively, but are not limited thereto. The ceramic particle may be formed of a prismatic particle having a random shape by pulverizing ceramic particles having a bulk form, but is not limited thereto.

In the disposing (S2) of the ceramic particles on the surfaces of the metal particles, as shown in FIG. 3B, the ceramic particles may be physically attached to the surface of the metal particles by mixing the metal particles 1 and the ceramic particles 2 with each other and then applying physical impact to mixtures of the metal particles 1 and the ceramic particles 2. The metal particles and the ceramic particles may be mixed with each other by a mechanical mixing method.

In the forming (S3) of the oxidized layers on the exposed surfaces of the metal particles, as shown in FIG. 3C, the surfaces of the metal particles on which the ceramic particles are not disposed may be oxidized to allow the surface of the metal particles to include the oxidized layers 3, which may be performed by heat treatment at a temperature of 800° C. to 1000° C. under an oxidizing atmosphere.

Next, the composite fillers 10 formed of the metal particles and the ceramic particles disposed on the surfaces of the metal particles and the base resin 20 may be mixed with each other to form the prepreg 120′ as shown in FIG. 3D. The prepreg 120′ may be completely hardened to form the heat radiation sheet.

### Heat Radiation Board

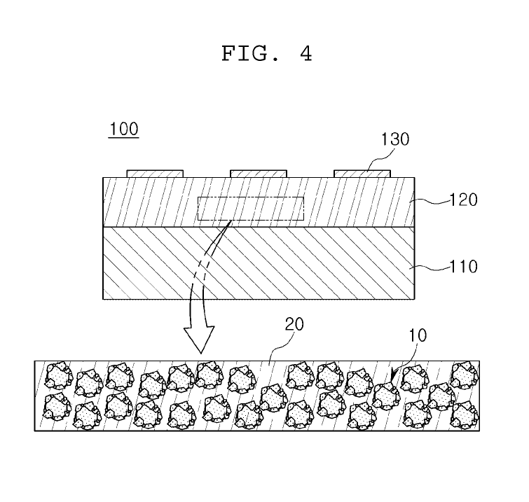

FIG. 4 is a cross-sectional view schematically showing a heat radiation board according to another exemplary embodiment in the present disclosure.

Referring to FIG. 4, a heat radiation board 100 according to the present exemplary embodiment may include a metal plate 110, a heat radiation sheet 120, and a metal layer 130.

The metal plate 110 may serve as a heat sink and may include one or more of copper, aluminum, nickel, gold, silver, and platinum having good thermal conductivity, but is not limited thereto.

The heat radiation sheet 120 may allow the metal plate and the metal layer to be adhered to each other, and serve to electrically insulate the metal plate and the metal layer from each other, and transfer heat to the metal plate.

The metal layer 130 may be a circuit pattern, and may include copper, but is not limited thereto.

The heat radiation sheet 120 may be the heat radiation sheet for a board according to an exemplary embodiment in the present disclosure. A detailed description for the heat radiation sheet will be omitted in order to avoid an overlapped description.

As set forth above, according to exemplary embodiments of the present disclosure, the heat radiation sheet having the improved thermal conduction efficiency, the manufacturing method thereof, and the heat radiation board may be provided.

While exemplary embodiments have been shown and described above, it will be apparent to those skilled in the art that modifications and variations could be made without departing from the scope of the present invention as defined by the appended claims.

What is claimed is:

1. A heat radiation sheet for a board, comprising:
composite fillers including metal particles and ceramic particles disposed on surfaces of the metal particles; and
a base resin.

2. The heat radiation sheet for a board of claim 1, wherein the metal particles include oxidized layers formed by oxidizing surfaces of regions in which the ceramic particles are not disposed.

3. The heat radiation sheet for a board of claim 2, wherein a thickness of the oxidized layer is (Volume of Ceramic Particles/Volume of Metal Particles)^{1/3}×1.5 μm or more.

4. The heat radiation sheet for a board of claim 1, wherein a volume ratio between the metal particles and the ceramic particles is 10:8 to 10:28.

5. The heat radiation sheet for a board of claim 1, wherein the metal particle is a non-magnetic metal particle.

6. The heat radiation sheet for a board of claim 1, wherein a particle size of the composite filler is 0.1 to 0.15 times the thickness of the heat radiation sheet.

7. The heat radiation sheet for a board of claim 1, wherein a hardness of the ceramic particle is greater than that of the metal particle.

8. The heat radiation sheet for a board of claim 1, wherein a particle size of the ceramic particle is 0.3 to 1.4 times the particle size of the metal particle.

9. The heat radiation sheet for a board of claim 1, wherein the ceramic particles are attached to the surfaces of the metal particles by physical coupling force.

10. The heat radiation sheet for a board of claim 1, wherein the metal particle includes one or more of copper (Cu), aluminum (Al), tin (Sn), and titanium (Ti).

11. The heat radiation sheet for a board of claim 1, wherein the ceramic particle includes one or more of alumina (Al₂O₃), aluminum nitride (AlN), boron nitride (BN), silicon dioxide (SiO₂), and silicon carbide (SiC).

12. The heat radiation sheet for a board of claim 1, wherein the ceramic particle has a prismatic shape.

13. A manufacturing method of a heat radiation sheet for a board, comprising:
preparing metal particles and ceramic particles;
disposing the ceramic particles on surfaces of the metal particles by mixing the metal particles and the ceramic particles with each other;
forming oxidized layers on exposed surfaces of the metal particles; and
forming a prepreg by mixing composite fillers including the metal particles and the ceramic particles and a base resin with each other.

14. The manufacturing method of a heat radiation sheet for a board of claim 13, further comprising, after the forming of the prepreg, forming the heat radiation sheet by hardening the base resin included in the prepreg.

15. The manufacturing method of a heat radiation sheet for a board of claim 13, wherein a volume ratio between the metal particles and the ceramic particles is 10:8 to 10:28.

16. The manufacturing method of a heat radiation sheet for a board of claim 13, wherein the ceramic particles are attached to the surfaces of the metal particles by physical coupling force.

17. The manufacturing method of a heat radiation sheet for a board of claim 13, wherein the forming of the oxidized layers is performed by heat treatment at a temperature of 800° C. to 1000° C. under an oxidizing atmosphere.

18. The manufacturing method of a heat radiation sheet for a board of claim 13, wherein the metal particle is a non-magnetic metal particle.

19. A heat radiation board comprising:
a metal plate;
a heat radiation sheet including composite fillers including metal particles and ceramic particles disposed on surfaces of the metal particles and a base resin, and disposed on the metal plate; and
a metal layer disposed on the heat radiation sheet.

20. The heat radiation board of claim 19, wherein the metal particles include oxidized layers formed by oxidizing surfaces of regions in which the ceramic particles are not disposed.
